(19) United States
(12) Patent Application Publication
(10) Pub. No.: US 2026/0164694 A1
(43) Pub. Date: Jun. 11, 2026

(54) SEMICONDUCTOR DEVICE

(71) Applicant: SAMSUNG ELECTRONICS CO., LTD., Suwon-si (KR)

(72) Inventors: Boram KIM, Suwon-si (KR); Jongseob KIM, Suwon-si (KR); Joonyong KIM, Suwon-si (KR); Junhyuk PARK, Suwon-si (KR)

(73) Assignee: SAMSUNG ELECTRONICS CO., LTD., Suwon-si (KR)

(21) Appl. No.: 19/182,039

(22) Filed: Apr. 17, 2025

(30) Foreign Application Priority Data
Nov. 14, 2021 (KR) 10-2024-0162428

(51) Int. Cl. H10D 30/47; H10D 62/17; H10D 64/68

(52) U.S. Cl. CPC H10D 30/471; H10D 62/235; H10D 64/685

(57) ABSTRACT

A semiconductor device includes a channel layer, a barrier layer located on the channel layer and including a material having an energy bandgap different from that of the channel layer, a gate electrode layer located on the barrier layer and extending in a first direction, a gate semiconductor layer disposed between the barrier layer and the gate electrode layer, and a source electrode and a drain electrode connected to the channel layer and spaced apart from the gate electrode layer in a second direction different from the first direction, in which the gate semiconductor layer includes a gate semiconductor material layer disposed on the barrier layer, and an oxide layer disposed between the gate semiconductor material layer and the gate electrode layer.

### CROSS-REFERENCE TO RELATED APPLICATION

This application claims priority to and the benefit of Korean Patent Application No. 10-2024-0162428 filed in the Korean Intellectual Property Office on Nov. 14, 2024, the entire contents of which are incorporated herein by reference.

### BACKGROUND

The present disclosure relates to a semiconductor device.

In modern society, semiconductor devices are closely related to daily life. In particular, the importance of power semiconductor devices used in various fields such as transportation fields such as electric vehicles, railroads, and electric trams, renewable energy systems such as solar power generation and wind power generation, and mobile devices is gradually increasing. Power semiconductor devices are semiconductor devices used to handle high voltage or high current, and perform functions such as power conversion and control in large power systems or high-output electronic devices. Power semiconductor devices have the ability and durability to handle high power, so they can handle large amounts of current and withstand high voltage. For example, power semiconductor devices can handle voltages from hundreds of volts to thousands of volts and currents from tens of amperes to thousands of amperes. Power semiconductor devices can improve the efficiency of electrical energy by minimizing power loss. Additionally, power semiconductor devices can be stably driven even in environments such as high temperatures.

These power semiconductor devices can be classified according to materials, and examples include SiC power semiconductor devices and GaN power semiconductor devices. Power semiconductor devices are manufactured using SiC or GaN instead of existing silicon (Si), and thereby the disadvantage of silicon, which has unstable characteristics at high temperatures, can be compensated. The SiC power semiconductor devices are resistant to high temperatures and have low power loss, and can be suitable for electric vehicles, renewable energy systems, etc. The GaN power semiconductor devices require high costs, but are efficient in terms of speed and can be suitable for high-speed charging of mobile devices.

### SUMMARY

One aspect of the present disclosure provides a semiconductor device capable of increasing the activation efficiency of an acceptor while lowering the temperature of an activation process, forming an oxide layer on the surface of a gate semiconductor layer to reduce the content of impurities such as oxygen, carbon, and hydrogen in the gate semiconductor layer, preventing surface roughness from increasing, strengthening depletion of the gate semiconductor layer, and suppressing gate leakage current.

A semiconductor device according to one aspect includes a channel layer, a barrier layer located on the channel layer and including a material having an energy bandgap different from that of the channel layer, a gate electrode layer located on the barrier layer and extending in a first direction, a gate semiconductor layer disposed between the barrier layer and the gate electrode layer, and a source electrode and a drain electrode connected to the channel layer and spaced apart from the gate electrode layer in a second direction different from the first direction, in which the gate semiconductor layer includes a gate semiconductor material layer disposed on the barrier layer, and an oxide layer disposed between the gate semiconductor material layer and the gate electrode layer.

A semiconductor device according to another aspect includes a channel layer, a barrier layer located on the channel layer and including a material having an energy bandgap different from that of the channel layer, a gate electrode layer located on the barrier layer and extending in a first direction, a gate semiconductor layer disposed between the barrier layer and the gate electrode layer, and a source electrode and a drain electrode connected to the channel layer and spaced apart from the gate electrode layer in a second direction different from the first direction, in which the gate semiconductor layer has an oxygen concentration less than or equal to about 5E17 atom/cm³ as measured by secondary ion mass spectrometry (SIMS).

A semiconductor device according to another aspect includes a channel layer, a barrier layer located on the channel layer and including a material having an energy bandgap different from that of the channel layer, a gate electrode layer located on the barrier layer and extending in a first direction, a gate semiconductor layer disposed between the barrier layer and the gate electrode layer, and a source electrode and a drain electrode connected to the channel layer and spaced apart from the gate electrode layer in a second direction different from the first direction, in which the gate semiconductor layer includes a gate semiconductor material layer disposed on the barrier layer, and an oxide layer disposed between the gate semiconductor material layer and the gate electrode layer, and the gate semiconductor material layer has an oxygen concentration less than or equal to about 5E17 atom/cm³ as measured by secondary ion mass spectrometry (SIMS), and the oxide layer has an oxygen concentration greater than or equal to about 1E18 atom/cm³ as measured by secondary ion mass spectrometry.

The semiconductor device according to the embodiments can increase the activation efficiency of an acceptor while lowering the temperature of an activation process, form an oxide layer on the surface of a gate semiconductor layer to reduce the content of impurities such as oxygen, carbon, and hydrogen in the gate semiconductor layer, prevent surface roughness from increasing, strengthen gate semiconductor layer depletion, and suppress gate leakage current.

### BRIEF DESCRIPTION OF THE DRAWINGS

FIG. 1 is a plan view showing a semiconductor device according to one embodiment.

FIG. 2 is a cross-sectional view taken along line A-A′ of FIG. 1.

FIG. 3 is an enlarged cross-sectional view of portion P of FIG. 2.

FIG. 4 is an enlarged cross-sectional view of portion P of FIG. 2, showing another embodiment.

FIG. 5 is an enlarged cross-sectional view of portion P of FIG. 2, showing another embodiment.

FIGS. 6, 7, 8, 9 and 10 are cross-sectional views showing a method for manufacturing a semiconductor device according to embodiments in the order of processes.

### DETAILED DESCRIPTION OF THE EMBODIMENTS

Hereinafter, various embodiments of the present disclosure will be described in detail with reference to the attached drawings so that a person having ordinary skill in the art to which the present disclosure pertains can easily implement the present disclosure. The present disclosure may be embodied in many different forms and is not limited to the embodiments set forth herein.

The drawings and description are to be regarded as illustrative in nature and not restrictive. Like reference numerals designate like elements throughout the specification.

The size and thickness of each constituent element as shown in the drawings are randomly indicated for better understanding and ease of description, and this disclosure is not necessarily limited to as shown. In the drawings, the thickness of layers, regions, etc., are exaggerated for clarity. In addition, in the drawings, for better understanding and ease of description, the thickness of some layers and areas is exaggerated.

It will be understood that when an element such as a layer, film, region, or substrate is referred to as being “on” another element, it can be directly on the other element or intervening elements may also be present. In contrast, when an element is referred to as being “directly on” another element, there are no intervening elements present. The word “on” or “above” means being disposed on or below the object portion, and does not necessarily mean being disposed on the upper side of the object portion based on a gravitational direction.

In addition, unless explicitly described to the contrary, the word “comprise,” and variations such as “comprises” or “comprising,” will be understood to imply the inclusion of stated elements but not the exclusion of any other elements.

In addition, in this specification, the phrase “on a plane” means viewing a target portion from the top, and the phrase “on a cross-section” means viewing a cross-section formed by vertically cutting a target portion from the side.

In addition, throughout the specification, two directions parallel to and intersecting the upper surface of the substrate are defined as the first direction D1 and the second direction D2, respectively, and the direction perpendicular to the upper surface of the substrate is described as the third direction D3. For example, the first direction D1 and the second direction D2 may be perpendicular to each other.

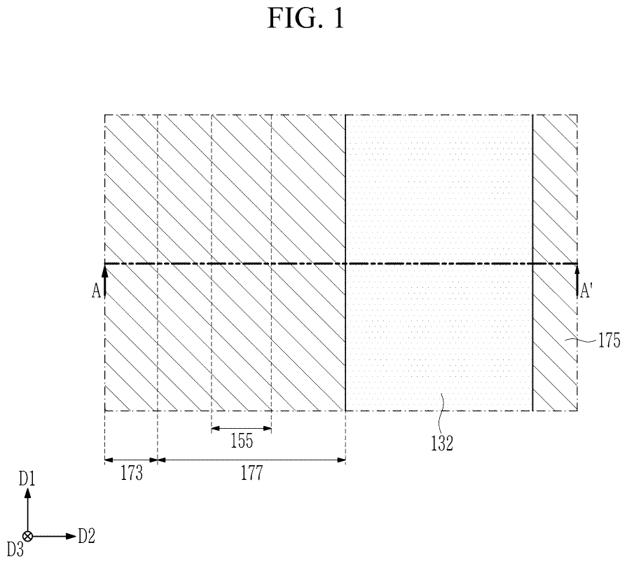

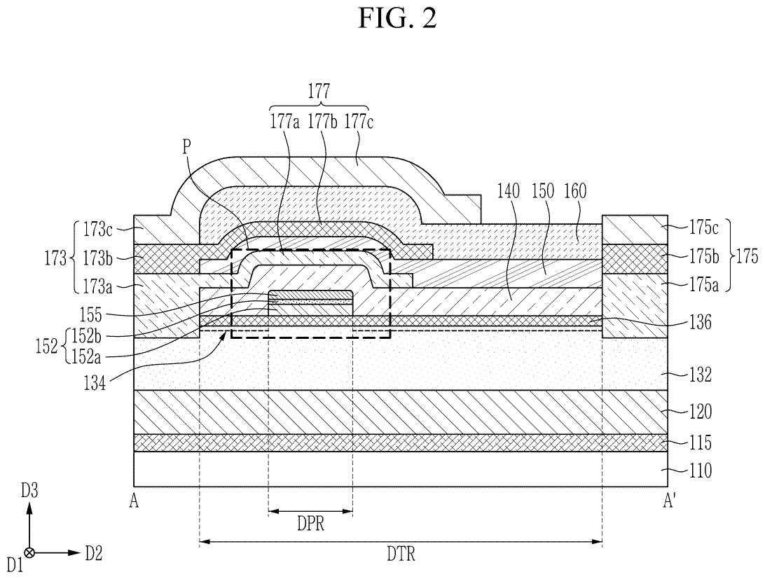

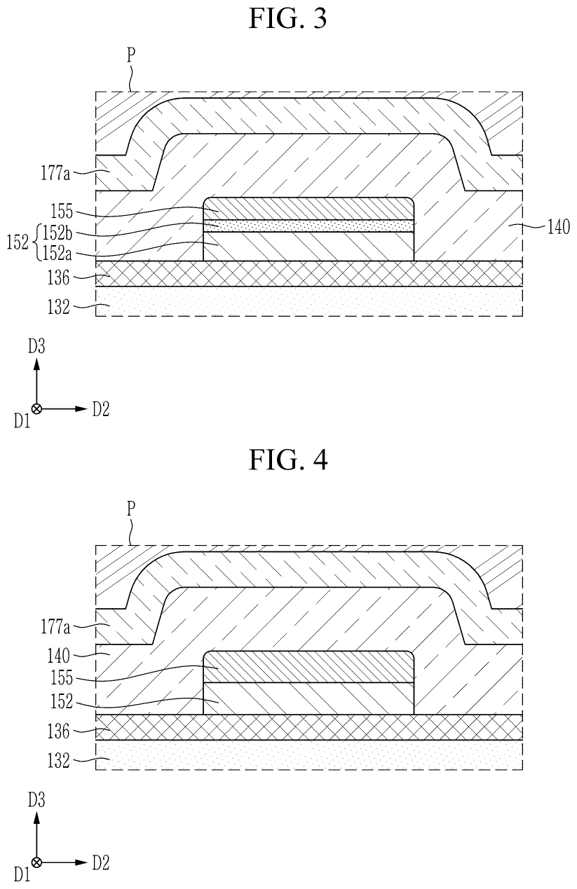

FIG. 1 is a plan view showing a semiconductor device according to an embodiment. FIG. 2 is a cross-sectional view taken along line A-A′ of FIG. 1. FIG. 3 is an enlarged cross-sectional view of portion P of FIG. 2.

For clear understanding and simple illustration, FIG. 1 mainly depicts the channel layer 132, the gate electrode layer 155, the source electrode 173, the field dispersion layer 177, and the drain electrode 175.

Referring to FIGS. 1 to 3, the semiconductor device includes a channel layer 132, a barrier layer 136 on the channel layer 132, a gate electrode layer 155 on the barrier layer 136, a gate semiconductor layer 152 between the barrier layer 136 and the gate electrode layer 155, and a source electrode 173 and a drain electrode 175 located on both sides of the gate electrode layer 155 and connected to the channel layer 132.

The channel layer 132 is a layer that forms a channel between the source electrode 173 and the drain electrode 175, and a two-dimensional electron gas (2DEG) 134 can be located inside the channel layer 132. The two-dimensional electron gas 134 is a charge transport model used in solid-state physics, and refers to a group of electrons that can move freely in two dimensions (e.g., in the D1-D2 plane direction) but cannot move in another dimension (e.g., in the D3 direction) and are tightly bound within the two dimensions. That is, the two-dimensional electron gas 134 can exist in a two-dimensional paper-like form within a three-dimensional space. This two-dimensional electron gas 134 mainly appears in a semiconductor heterojunction structure, and in a semiconductor device according to an embodiment, it can occur at the interface between the channel layer 132 and the barrier layer 136. For example, a two-dimensional electron gas 134 may be generated in the portion closest to the barrier layer 136 within the channel layer 132.

The channel layer 132 may include nitride including Group III-V materials, for example, Al, Ga, In, B, or a combination thereof. The channel layer 132 may be made of a single layer or multiple layers. As an example, the channel layer 132 may include AlₓIn_{y}Ga_{1-x-y}N (0≤x≤1, 0≤y≤1, x+y≤1). For example, the channel layer 132 may include AlN, GaN, InN, InGaN, AlGaN, AlInN, AlInGaN, or a combination thereof. The channel layer 132 may be a layer doped with impurities or a layer undoped with impurities. A thickness of the channel layer 132 may be about several hundred nm or less.

The channel layer 132 may be located on the substrate 110, and a seed layer 115, or a buffer layer 120 may be located between the substrate 110 and the channel layer 132. The substrate 110, the seed layer 115, and the buffer layer 120 are layers necessary to form the channel layer 132, and may be omitted in some cases. For example, when a substrate made of GaN is used as the channel layer 132, at least one of the substrate 110, the seed layer 115, and the buffer layer 120 may be omitted. Considering that the price of a substrate made of GaN is relatively high, the channel layer 132 including GaN can be grown using the substrate 110 made of Si. At this time, as the lattice structure of Si and GaN are different, it may not be easy to grow the channel layer 132 directly on the substrate 110. Accordingly, the seed layer 115 and the buffer layer 120 can be first grown on the substrate 110, and then the channel layer 132 can be grown on the buffer layer 120. Additionally, at least one of the substrate 110, the seed layer 115, and the buffer layer 120 may be removed from the final structure of the semiconductor device after being used in the manufacturing process.

The substrate 110 may include a semiconductor material. For example, the substrate 110 may include sapphire, Si, SiC, AlN, GaN, diamond, glass, or a combination thereof. The substrate 110 may be a silicon on insulator (SOI) substrate. However, the material of the substrate 110 is not limited to this, and any commonly used substrate can be applied. In some cases, the substrate 110 may include an insulating material. For example, several layers, including the channel layer 132, may be first formed on a semiconductor substrate, then the semiconductor substrate may be removed and replaced with an insulating substrate.

The seed layer 115 may be located on the substrate 110. The seed layer 115 may be located directly on the substrate 110. However, it is not limited to this, and another predetermined layer may be further located between the substrate 110 and the seed layer 115. The seed layer 115 is a layer that serves as a seed for growing the buffer layer 120, and may be made of a crystal lattice structure that serves as a seed for the buffer layer 120. For example, the seed layer 115 may include AlN, but is not limited thereto.

The buffer layer 120 may be located on the seed layer 115. The buffer layer 120 may be located directly on the seed layer 115. However, it is not limited to this, and another predetermined layer may be further located between the seed layer 115 and the buffer layer 120. The buffer layer 120 may be located between the seed layer 115 and the channel layer 132. The buffer layer 120 may include nitride including Group III-V materials, for example, Al, Ga, In, B, or a combination thereof. The buffer layer 120 may include AlₓIn_{y}Ga_{1-x-y}N (0≤x≤1, 0≤y≤1, x+y≤1). For example, the buffer layer 120 may include AlN, GaN, InN, InGaN, AlGaN, AlInN, AlInGaN, or a combination thereof. The buffer layer 120 may be made of a single layer or multiple layers. For example, the buffer layer 120 may include a superlattice layer and a high-resistance layer.

The superlattice layer alleviates a difference in lattice constant and thermal expansion coefficient between the substrate 110 and the channel layer 132, thereby relieving tensile stress and compressive stress generated between the substrate 110 and the channel layer 132.

The high-resistance layer may be located on the superlattice layer. For example, the high-resistance layer may be located directly on the superlattice layer. However, the present disclosure is not limited to this, and other layers may be located between the superlattice layer and the high-resistance layer. The high-resistance layer may be located between the superlattice layer and the channel layer 132. The high-resistance layer can prevent the semiconductor element from deteriorating by preventing leakage current from flowing through the channel layer 132. The high-resistance layer may be made of a low-conductivity material to electrically insulate the substrate 110 and the channel layer 132.

For example, the high-resistance layer can have a resistance value of greater than or equal to about 1.0×10⁶ Ω·cm. For example, the resistance value of the high-resistance layer may be greater than or equal to about 1.0×10¹⁰ Ω·cm. As another example, the resistance value of the high-resistance layer can be greater than or equal to about 1.0×10¹² Ω·cm. Resistance values can be measured by forming a measuring electrode within a high-resistance layer and allowing current to flow.

The high-resistance layer may include a nitride including Group III-V materials, such as Al, Ga, In, B, or a combination thereof. The high-resistance layer may include AlₓIn_{y}Ga_{1-x-y}N (0≤x≤1, 0≤y≤1, x+y≤1), and may include, for example, AlN, GaN, InN, InGaN, AlGaN, AlInN, AlInGaN, or a combination thereof. The high-resistance layer may be composed of a single layer or multiple layers.

The barrier layer 136 may be located on the channel layer 132. The barrier layer 136 may be located directly on the channel layer 132. However, it is not limited to this, and another predetermined layer may be further located between the channel layer 132 and the barrier layer 136. A region of the channel layer 132 that is overlapped with the barrier layer 136 may be a drift region DTR. The drift region DTR may be located between the source electrode 173 and the drain electrode 175. When a potential difference occurs between the source electrode 173 and the drain electrode 175, carriers may move in the drift region DTR. The semiconductor device may be turned on/off depending on whether a voltage is applied to the gate electrode layer 155 and the magnitude of the voltage applied to the gate electrode layer 155. When a voltage greater than the threshold voltage is applied to the gate electrode layer 155 and the semiconductor device is turned on, a channel may be created in the depletion region DPR. Accordingly, movement of the carrier may occur in the drift region DTR. If a voltage lower than the threshold voltage is applied to the gate electrode layer 155 or no voltage is applied, the channel path may be blocked in the depletion region DPR and carrier movement may not occur.

The barrier layer 136 may include nitride including Group III-V materials, for example, Al, Ga, In, B, or a combination thereof. The barrier layer 136 may include AlₓIn_{y}Ga_{1-x-y}N (0≤x≤1, 0≤y≤1, x+y≤1). For example, the barrier layer 136 may include AlN, GaN, InN, InGaN, AlGaN, AlInN, AlInGaN, or a combination thereof. The energy bandgap of the barrier layer 136 can be adjusted by a composition ratio of Al or In.

The barrier layer 136 may include a semiconductor material having different characteristics from the channel layer 132. The barrier layer 136 may be different from the channel layer 132 in at least one of polarization characteristics, energy bandgap, and lattice constant. For example, the barrier layer 136 may include a material having a different energy bandgap than the channel layer 132. At this time, the barrier layer 136 may have a higher energy bandgap than the channel layer 132 and may have a higher electrical polarization rate than the channel layer 132. The two-dimensional electron gas 134 may be induced in the channel layer 132, which has a relatively low electrical polarization rate, by the barrier layer 136. In this regard, the barrier layer 136 may also be called a channel supply layer or a two-dimensional electron gas supply layer. The two-dimensional electron gas 134 may be formed within the portion of the channel layer 132 under the interface between the channel layer 132 and the barrier layer 136. The two-dimensional electron gas 134 may have very high electron mobility.

The gate electrode layer 155 may be located on the barrier layer 136. The gate electrode layer 155 may be overlapped with a portion of the barrier layer 136 in the third direction D3. The gate electrode layer 155 may be overlapped with a portion of the drift region DTR of the channel layer 132 in the third direction D3. The gate electrode layer 155 may be located between the source electrode 173 and the drain electrode 175 in the second direction D2. The gate electrode layer 155 may be spaced apart from the source electrode 173 and the drain electrode 175 in the second direction D2. The gate electrode layer 155 may extend along the first direction D1 on a plane. In other words, the gate electrode layer 155 may have a bar shape extending long along the first direction D1 on a plane.

The gate electrode layer 155 may include a conductive material. For example, the gate electrode layer 155 may include a metal, a metal alloy, conductive metal nitride, metal silicide, a doped semiconductor material, conductive metal oxide, or conductive metal oxynitride. For example, the gate electrode layer 155 may be made of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium. (Rh), palladium (Pd), iridium (Ir), osmium (Os), silver (Ag), gold (Au), zinc (Zn), vanadium (V), or a combination thereof, but is not limited thereto. The gate electrode layer 155 may be made of a single layer or multiple layers.

In some embodiments, a hardmask layer (not shown) may further be included on the gate electrode layer 155. The hardmask layer may be a hardmask used when patterning a gate electrode material layer or a gate semiconductor layer in the process of forming a gate electrode layer 155. However, the hardmask layer may be removed depending on the etching conditions during the etching of the gate electrode material layer or depending on the cleaning conditions after etching. For example, the hardmask layer may include silicon oxide, silicon nitride, silicon oxynitride, or a combination thereof.

The gate semiconductor layer 152 is located between the barrier layer 136 and the gate electrode layer 155. That is, the gate semiconductor layer 152 may be located on the barrier layer 136, and the gate electrode layer 155 may be located on the gate semiconductor layer 152. The gate electrode layer 155 may be in Schottky contact with the gate semiconductor layer 152. However, it is not limited to this, and in some cases, the gate electrode layer 155 may be in ohmic contact with the gate semiconductor layer 152. The gate semiconductor layer 152 may be overlapped with the gate electrode layer 155 in the third direction D3. The upper surface of the gate semiconductor layer 152 may be entirely covered by the gate electrode layer 155.

The gate semiconductor layer 152 may be located between the source electrode 173 and the drain electrode 175 in the second direction D2. The gate semiconductor layer 152 may be spaced apart from the source electrode 173 and the drain electrode 175 in the second direction D2. The gate semiconductor layer 152 may be located closer to the source electrode 173 than the drain electrode 175. That is, a separation distance between the gate semiconductor layer 152 and the source electrode 173 may be smaller than a separation distance between the gate semiconductor layer 152 and the drain electrode 175.

A depletion region DPR may be formed in the channel layer 132 by the gate semiconductor layer 152. A depletion region DPR may be formed in the channel layer 132 by the gate semiconductor layer 152. The depletion region DPR may be located within the drift region DTR and may have a narrower width than the drift region DTR. As the gate semiconductor layer 152 having a different energy bandgap from the barrier layer 136 is located on the barrier layer 136, a level of the energy band of a portion of the barrier layer 136 that is overlapped with the gate semiconductor layer 152 may increase. Accordingly, the depletion region DPR may be formed in the area of the channel layer 132 that is overlapped with the gate semiconductor layer 152. The depletion region DPR may be a region in the channel path of the channel layer 132 where the two-dimensional electron gas 134 is not formed or may have a lower electron concentration than the remaining regions. That is, the depletion region DPR may refer to a region where the flow of the two-dimensional electron gas 134 is interrupted within the drift region DTR. As the depletion region DPR is generated, current does not flow between the source electrode 173 and the drain electrode 175, and the channel path may be blocked. Accordingly, the semiconductor device may have normally-Off characteristics.

In other words, the semiconductor device may be a normally-off semiconductor device (HEMT, High Electron Mobility Transistor). In a normal state in which no voltage is applied to the gate electrode layer 155, a depletion region DPR exists and the semiconductor device may be in an off state. When a voltage higher than the threshold voltage is applied to the gate electrode layer 155, the depletion region DPR disappears, and the two-dimensional electron gas 134 may be connected without being disconnected within the drift region DTR. That is, the two-dimensional electron gas 134 may be formed throughout the channel path between the source electrode 173 and the drain electrode 175, and the semiconductor device may be in an on state. In summary, the semiconductor device may include semiconductor layers with different electrical polarization characteristics, and a semiconductor layer with a relatively high polarization rate can induce two-dimensional electron gas 134 in another semiconductor layer that forms heterojunction therewith. This two-dimensional electron gas 134 can be used as a channel between the source electrode 173 and the drain electrode 175, and the continuation or interruption of the flow of the two-dimensional electron gas 134 can be controlled by the bias voltage applied to the gate electrode layer 155. In the gate-off state, the flow of the two-dimensional electron gas 134 is blocked, and thus current may not flow between the source electrode 173 and the drain electrode 175. In the gate-on state, the two-dimensional electron gas 134 continues to flow, and thus current may flow between the source electrode 173 and the drain electrode 175.

Although the case where the semiconductor device is a normally-off high electron mobility transistor has been described above, the present disclosure is not limited thereto. For example, the semiconductor device may be a normally-on high electron mobility transistor. In the case of a normally-on high electron mobility transistor, the gate semiconductor layer 152 may be omitted, and accordingly, the gate electrode layer 155 may be located directly on the barrier layer 136. That is, the gate electrode layer 155 may contact the barrier layer 136. However, the present disclosure is not limited thereto, and a gate dielectric layer may be interposed between the gate electrode layer 155 and the barrier layer 136. In this structure, the two-dimensional electron gas 134 can be used as a channel while no voltage is applied to the gate electrode layer 155, and current may flow between the source electrode 173 and the drain electrode 175. Additionally, when a negative voltage is applied to the gate electrode layer 155, a depletion region DPR in which the flow of the two-dimensional electron gas 134 is cut off may be generated at the bottom of the gate electrode layer 155.

For example, in order to manufacture a GaN power semiconductor device having normally off characteristics, an activation process of the gate semiconductor layer 152 is required. For example, a method of activating a gate semiconductor layer 152 including p-type GaN doped with magnesium (Mg) is to apply heat in a nitrogen (N₂) atmosphere. However, during this process, changes such as the mixing of impurities such as oxygen, carbon, and hydrogen and the increase in surface roughness may occur due to the high temperature treatment.

As described below, by activating the gate semiconductor material layer 152a in an oxygen atmosphere, the activation efficiency of the acceptor can be increased while lowering the temperature of the activation process, an oxide layer 152b can be formed on the surface of the gate semiconductor material layer 152a, the content of impurities such as oxygen, carbon, and hydrogen in the gate semiconductor material layer 152a can be reduced, surface roughness can be prevented from increasing, depletion can be strengthened in the depletion region DPR under the gate semiconductor layer 152, and gate leakage current can be suppressed.

Accordingly, the gate semiconductor layer 152 may include a gate semiconductor material layer 152a and an oxide layer 152b.

The gate semiconductor material layer 152a may be located on the barrier layer 136. For example, a gate semiconductor material layer 152a may be located on a barrier layer 136, an oxide layer 152b may be located on the gate semiconductor material layer 152a, and a gate electrode layer 155 may be located on the oxide layer 152b. The upper surface of the gate semiconductor material layer 152a may be entirely covered by an oxide layer 152b. The gate semiconductor material layer 152a may be overlapped with the gate electrode layer 155 in the third direction D3.

The gate semiconductor material layer 152a may include a nitride including a Group III-V material, for example, Al, Ga, In, B, or a combination thereof. The gate semiconductor material layer 152a may include AlₓIn_{y}Ga_{1-x-y}N (0≤x≤1, 0≤y≤1, x+y≤1). For example, the gate semiconductor material layer 152 a may include AlN, GaN, InN, InGaN, AlGaN, AlInN, AlInGaN, or a combination thereof. The gate semiconductor material layer 152a may include a material having a different energy band gap from the barrier layer 136. For example, the gate semiconductor material layer 152a may include GaN, and the barrier layer 136 may include AlGaN.

The gate semiconductor material layer 152a may be doped with a predetermined impurity. At this time, the impurity doped into the gate semiconductor material layer 152a may be a p-type dopant capable of providing holes. For example, the gate semiconductor material layer 152a may include GaN doped with p-type impurities. That is, the gate semiconductor material layer 152a may be formed of a p-GaN layer. However, it is not limited thereto, and the gate semiconductor material layer 152a may be a p-AlGaN layer. The impurity doped into the gate semiconductor material layer 152a may be magnesium (Mg). The gate semiconductor material layer 152a may be formed of a single layer or multiple layers.

The oxide layer 152b may be located on the gate semiconductor material layer 152a. In other words, the oxide layer 152b may be located between the gate semiconductor material layer 152a and the gate electrode layer 155. For example, an oxide layer 152b may be located on a gate semiconductor material layer 152a, and a gate electrode layer 155 may be located on the oxide layer 152b. The upper surface of the gate semiconductor material layer 152a may be entirely covered by an oxide layer 152b. The oxide layer 152b may be overlapped with the gate semiconductor material layer 152a and the gate electrode layer 155 in the third direction D3. The upper surface of the oxide layer 152b may be entirely covered by a gate electrode layer 155.

Since the oxide layer 152b is formed by activating the gate semiconductor material layer 152a in an oxygen atmosphere, it may contain oxygen.

For example, the oxide layer 152b may have an oxygen concentration greater than or equal to about 1E18 atom/cm³, for example, greater than or equal to about 2E18 atom/cm³, greater than or equal to about 3E18 atom/cm³, greater than or equal to about 4E18 atom/cm³, greater than or equal to about 5E18 atom/cm³, greater than or equal to about 6E18 atom/cm³, greater than or equal to about 7E18 atom/cm³, greater than or equal to about 8E18 atom/cm³, or greater than or equal to about 9E18 atom/cm³ as measured by secondary ion mass spectrometry. The oxide layer 152b may have an oxygen concentration less than or equal to about 1E19 atom/cm³, for example, less than or equal to about 9E18 atom/cm³, less than or equal to about 8E18 atom/cm³, less than or equal to about 7E18 atom/cm³, less than or equal to about 6E18 atom/cm³, less than or equal to about 5E18 atom/cm³, less than or equal to about 4E18 atom/cm³, less than or equal to about 3E18 atom/cm³, or less than or equal to about 2E18 atom/cm³ as measured by secondary ion mass spectrometry. The oxide layer 152b may have an oxygen concentration ranging from about 1E18 atom/cm³ to about 1E19 atom/cm³ as measured by secondary ion mass spectrometry.

Here, the oxygen concentration of the oxide layer 152b may be measured by secondary ion mass spectrometry (SIMS) using an oxygen ion source (6 kV) at a certain depth in the thickness direction of the oxide layer 152b (i.e., the third direction D3). The point at which the oxygen concentration of the oxide layer 152b is measured may be a middle point in the width direction of the oxide layer 152b (i.e., the second direction D2) and a middle point in the thickness direction of the oxide layer 152b (i.e., the third direction D3). For example, the depth at which the oxygen concentration of the oxide layer 152b is measured may be a point that is about 5 nm deep, about 4 nm deep, about 3 nm deep, about 2 nm deep, or about 1 nm deep from one surface of the oxide layer 152b.

Additionally, the oxide layer 152b may include the same material as the gate semiconductor material layer 152a except for oxygen. For example, the oxide layer 152b may include a nitride including Group III-V materials with the remainder content excluding oxygen, such as Al, Ga, In, B, or a combination thereof. The oxide layer 152b may include AlₓIn_{y}Ga_{1-x-y}N (0≤x≤1, 0≤y≤1, x+y≤1) with the remainder content excluding oxygen, and may include, for example, AlN, GaN, InN, InGaN, AlGaN, AlInN, AlInGaN, or a combination thereof. Additionally, the same material as the gate semiconductor material layer 152a included in the oxide layer 152b may also be doped with a predetermined impurity.

For example, the thickness of the oxide layer 152b may be greater than or equal to about 1 nm, and may be, for example, greater than or equal to about 2 nm, greater than or equal to about 3 nm, greater than or equal to about 4 nm, greater than or equal to about 5 nm, greater than or equal to about 6 nm, greater than or equal to about 7 nm, greater than or equal to about 8 nm, or greater than or equal to about 9 nm. The thickness of the oxide layer 152b may be less than or equal to about 10 nm, for example, less than or equal to about 9 nm, less than or equal to about 8 nm, less than or equal to about 7 nm, less than or equal to about 6 nm, less than or equal to about 5 nm, less than or equal to about 4 nm, less than or equal to about 3 nm, or less than or equal to about 2 nm. The thickness of the oxide layer 152b may be about 2 nm to about 5 nm.

Here, the thickness of the oxide layer 152b may be the shortest distance in the third direction D3 from the lower surface where the oxide layer 152b contacts the gate semiconductor material layer 152a to the upper surface where the oxide layer 152b contacts the gate electrode layer 155.

As the oxide layer 152b is located on the surface of the gate semiconductor material layer 152a, the content of impurities such as oxygen, carbon, and hydrogen in the gate semiconductor material layer 152a may be reduced and surface roughness may be prevented from increasing.

Accordingly, the oxygen concentration measured by secondary ion mass spectrometry of the oxide layer 152b may be greater than the oxygen concentration measured by secondary ion mass spectrometry of the gate semiconductor material layer 152a.

For example, the gate semiconductor material layer 152a may have an oxygen concentration less than or equal to about 5E17 atom/cm³, for example, less than or equal to about 4E17 atom/cm³, less than or equal to about 3E17 atom/cm³, less than or equal to about 2E17 atom/cm³, less than or equal to about 1E17 atom/cm³, less than or equal to about 9E16 atom/cm³, less than or equal to about 8E16 atom/cm³, less than or equal to about 7E16 atom/cm³, or less than or equal to about 6E16 atom/cm³ as measured by secondary ion mass spectrometry. The gate semiconductor material layer 152a may have an oxygen concentration greater than or equal to 0 atom/cm³, for example, greater than or equal to 1E16 atom/cm³, greater than or equal to 2E16 atom/cm³, greater than or equal to 3E16 atom/cm³, greater than or equal to 4E16 atom/cm³, greater than or equal to 5E16 atom/cm³, greater than or equal to 6E16 atom/cm³, greater than or equal to 7E16 atom/cm³, greater than or equal to 8E16 atom/cm³, or greater than or equal to 9E16 atom/cm³ as measured by secondary ion mass spectrometry. The gate semiconductor material layer 152a may have an oxygen concentration ranging from about 1E16 atom/cm³ to about 5E17 atom/cm³ as measured by secondary ion mass spectrometry.

Additionally, the gate semiconductor material layer 152a may have a carbon concentration less than about 1E18 atom/cm³, for example less than or equal to about 9E17 atom/cm³, less than or equal to about 8E17 atom/cm³, less than or equal to about 7E17 atom/cm³, less than or equal to about 6E17 atom/cm³, less than or equal to about 5E17 atom/cm³, less than or equal to about 4E17 atom/cm³, less than or equal to about 3E17 atom/cm³, or less than or equal to about 2E17 atom/cm³ as measured by secondary ion mass spectrometry. The gate semiconductor material layer 152a may have a carbon concentration greater than or equal to about 1E17 atom/cm³, for example greater than or equal to about 2E17 atom/cm³, greater than or equal to about 3E17 atom/cm³, greater than or equal to about 4E17 atom/cm³, greater than or equal to about 5E17 atom/cm³, greater than or equal to about 6E17 atom/cm³, greater than or equal to about 7E17 atom/cm³, greater than or equal to about 8E17 atom/cm³, or greater than or equal to about 9E17 atom/cm³. The gate semiconductor material layer 152a may have a carbon concentration greater than or equal to about 1E17 atom/cm³ and less than about 1E18 atom/cm³ as measured by secondary ion mass spectrometry.

Additionally, the gate semiconductor material layer 152a may have a hydrogen concentration less than about 1E18 atom/cm³, for example, for example less than or equal to about 9E17 atom/cm³, less than or equal to about 8E17 atom/cm³, less than or equal to about 7E17 atom/cm³, less than or equal to about 6E17 atom/cm³, less than or equal to about 5E17 atom/cm³, less than or equal to about 4E17 atom/cm³, less than or equal to about 3E17 atom/cm³, or less than or equal to about 2E17 atom/cm³ as measured by secondary ion mass spectrometry. The gate semiconductor material layer 152a may have a hydrogen concentration greater than or equal to about 1E17 atom/cm³, for example greater than or equal to about 2E17 atom/cm³, greater than or equal to about 3E17 atom/cm³, greater than or equal to about 4E17 atom/cm³, greater than or equal to about 5E17 atom/cm³, greater than or equal to about 6E17 atom/cm³, greater than or equal to about 7E17 atom/cm³, greater than or equal to about 8E17 atom/cm³, or greater than or equal to about 9E17 atom/cm³ as measured by secondary ion mass spectrometry. The gate semiconductor material layer 152a may have a hydrogen concentration greater than or equal to about 1E17 atom/cm³ and less than about 1E18 atom/cm³ as measured by secondary ion mass spectrometry.

For example, the oxygen concentration, carbon concentration, and hydrogen concentration of the gate semiconductor material layer 152a can be measured by secondary ion mass spectrometry (SIMS) using an oxygen ion source (6 kV) at a certain depth in the thickness direction (i.e., the third direction D3) of the gate semiconductor material layer 152a. The point at which the oxygen concentration, carbon concentration, and hydrogen concentration of the gate semiconductor material layer 152a are measured may be a middle point in the width direction of the gate semiconductor material layer 152a (i.e., the second direction D2) and a middle point in the thickness direction of the gate semiconductor material layer 152a (i.e., the third direction D3). For example, the depth at which the oxygen concentration, carbon concentration, and hydrogen concentration of the gate semiconductor material layer 152a are measured may be a point that is about 100 nm deep, about 90 nm deep, about 80 nm deep, about 70 nm deep, about 60 nm deep, about 50 nm deep, about 40 nm deep, about 30 nm deep, about 20 nm deep, about 10 nm deep, about 9 nm deep, about 8 nm deep, about 7 nm deep, about 6 nm deep, about 5 nm deep, about 4 nm deep, about 3 nm deep, about 2 nm deep, or about 1 nm deep from one surface of the gate semiconductor material layer 152a.

The semiconductor device may further include first to third protective layers 140, 150, and 160 located on the barrier layer 136 and the gate electrode layer 155. For example, the semiconductor device may include a first protective layer 140, a second protective layer 150 on the first protective layer 140, and a third protective layer 160 on the second protective layer 150. The first protective layer 140 may cover the upper surface of the barrier layer 136 and the gate electrode layer 155, and may cover the side surface of the gate electrode layer 155 and the side surface of the gate semiconductor layer 152. The lower surface of the first protective layer 140 may be in contact with the barrier layer 136, the gate electrode layer 155, and the gate semiconductor layer 152. The upper surface of the first protective layer 140 may be in contact with the second protective layer 150. The second to third protective layers 150 and 160 may be separated from the barrier layer 136, gate electrode layer 155, and gate semiconductor layer 152 by the first protective layer 140. Therefore, the second and third protective layers 150 and 160 may not be in contact with the barrier layer 136, the gate electrode layer 155, and the gate semiconductor layer 152.

The barrier layer 136 or the gate electrode layer 155, etc., may be protected by the first to third protective layers 140, 150, and 160 and may be separated from other components. The first to third protective layers 140, 150, and 160 may include an insulating material. For example, the first to third protective layers 140, 150, and 160 may include oxides such as SiO₂ or Al₂O₃. As another example, the first to third protective layers 140, 150, and 160 may include a nitride such as SiN or an oxynitride such as SiON. The first to third protective layers 140, 150, and 160 may include the same material or may include different materials. When the first to third protective layers 140, 150, and 160 are made of the same material, the boundaries between the first to fourth protective layers 156, 140, 150, and 160 may not be visible. The first to third protective layers 140, 150, and 160 may each be formed of a single layer or multiple layers.

The source electrode 173 and the drain electrode 175 may be located on the channel layer 132. The source electrode 173 and the drain electrode 175 may be spaced apart from each other in the second direction D2, and a gate electrode layer 155 and a gate semiconductor layer 152 may be located between the source electrode 173 and the drain electrode 175. The gate electrode layer 155 and the gate semiconductor layer 152 are spaced apart from the source electrode 173 and the drain electrode 175 in the second direction D2. The source electrode 173 may be electrically connected to the channel layer 132 on one side of the gate electrode layer 155. The drain electrode 175 may be electrically connected to the channel layer 132 on the other side of the gate electrode layer 155. The source electrode 173 and the drain electrode 175 may be located outside the drift region DTR of the channel layer 132. The interface between the source electrode 173 and the channel layer 132 may be one edge of the drift region DTR. Similarly, the interface between the drain electrode 175 and the channel layer 132 may be the other edge of the drift region DTR. However, the present disclosure is not limited thereto, and the source electrode 173 and the drain electrode 175 may not be located outside the drift region DTR of the channel layer 132. At this time, the channel layer 132 may not be recessed, and the source electrode 173 and the drain electrode 175 may be located on the upper surface of the channel layer 132. The bottom surfaces of the source electrode 173 and the drain electrode 175 may be in contact with the upper surface of the channel layer 132. Additionally, the barrier layer 136 may not be recessed. The source electrode 173 and the drain electrode 175 may be located on the upper surface of the barrier layer 136. In other words, the lower surfaces of the source electrode 173 and the drain electrode 175 may be in contact with the upper surface of the barrier layer 136. The portion of the channel layer 132 in contact with the source electrode 173 and the drain electrode 175 may be highly doped. At this time, carriers passing through the two-dimensional electron gas 134 can be transferred to the source electrode 173 and the drain electrode 175 through a portion of the channel layer 132 that is highly doped, i.e., the upper portion of the two-dimensional electron gas 134. The source electrode 173 and the drain electrode 175 may not be in direct horizontal contact with the two-dimensional electron gas 134. The horizontal direction may refer to a direction parallel to the upper surface of the channel layer 132 or the barrier layer 136.

The source electrode 173 and the drain electrode 175 may extend along the first direction D1 on a plane. That is, the source electrode 173 and the drain electrode 175 may have a rod shape extending long along the first direction D1 on a plane. The source electrode 173 and the drain electrode 175 may extend in parallel directions. The source electrode 173 and the drain electrode 175 may extend in a direction parallel to the gate electrode layer 155.

The source electrode 173 and the drain electrode 175 may include a conductive material. For example, the source electrode 173 and the drain electrode 175 may include a metal, a metal alloy, conductive metal nitride, metal silicide, a doped semiconductor material, conductive metal oxide, or conductive metal oxynitride. For example, the source electrode 173 and the drain electrode 175 may be made of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium. (Rh), palladium (Pd), iridium (Ir), osmium (Os), silver (Ag), gold (Au), zinc (Zn), vanadium (V), or a combination thereof, but are not limited thereto. The source electrode 173 and the drain electrode 175 may be made of a single layer or multiple layers. The source electrode 173 and the drain electrode 175 may be in ohmic contact with the channel layer 132. A region in contact with the source electrode 173 and the drain electrode 175 within the channel layer 132 may be doped at a relatively high concentration compared to other regions.

The source electrode 173 may include a lower source electrode 173a, a middle source electrode 173b, and an upper source electrode 173c. The middle source electrode 173b may be located on the lower source electrode 173a. The upper source electrode 173c may be located on the middle source electrode 173b. The lower source electrode 173a may be in direct contact with the channel layer 132 and may be electrically connected to the channel layer 132. The middle source electrode 173b and the upper source electrode 173c may not be in direct contact with the channel layer 132 and may be electrically connected to the channel layer 132 through the lower source electrode 173a.

The drain electrode 175 may include a lower drain electrode 175a, a middle drain electrode 175b, and an upper drain electrode 175c. The middle drain electrode 175b may be located on the lower drain electrode 175a. The upper drain electrode 175c may be located on the middle drain electrode 175b. The lower drain electrode 175a may be in direct contact with the channel layer 132 and may be electrically connected to the channel layer 132. The middle drain electrode 175b and the upper drain electrode 175c may not be in direct contact with the channel layer 132 and may be electrically connected to the channel layer 132 through the lower drain electrode 175a.

The lower source electrode 173a and the lower drain electrode 175a may be located on the first protective layer 140. The lower source electrode 173a and the lower drain electrode 175a may be located between the first protective layer 140 and the second protective layer 150. The lower source electrode 173a and the lower drain electrode 175a may penetrate the first protective layer 140 and the barrier layer 136, and the trenches that recess the upper surface of the channel layer 132 may be located so as to be spaced apart from each other on both sides of the gate electrode layer 155. The lower source electrode 173a and the lower drain electrode 175a may be located in trenches on both sides of the gate electrode layer 155, respectively. The lower source electrode 173a and the lower drain electrode 175a may be formed to fill the inside of the trench. Within the trench, the lower source electrode 173a and the lower drain electrode 175a may be in contact with the channel layer 132 and the barrier layer 136. The channel layer 132 may form the bottom surface and sidewalls of the trench, and the barrier layer 136 may form the sidewalls of the trench. Accordingly, the lower source electrode 173a and the lower drain electrode 175a may be in contact with the upper surface and side surface of the channel layer 132. Additionally, the lower source electrode 173a and the lower drain electrode 175a may be in contact with the side surface of the barrier layer 136. That is, the lower source electrode 173a and the lower drain electrode 175a may cover the side surfaces of the channel layer 132 and the barrier layer 136. The upper surfaces of the lower source electrode 173a and the lower drain electrode 175a may protrude more than the upper surface of the first protective layer 140. Additionally, at least one of the lower source electrode 173a and the lower drain electrode 175a may cover at least a portion of the upper surface of the first protective layer 140. A second protective layer 150 may be located on the lower source electrode 173a and the lower drain electrode 175a. At least a portion of the lower source electrode 173a and the lower drain electrode 175a may be covered by a second protective layer 150.

The semiconductor device may further include a first field dispersion layer 177a located on the first protective layer 140. The first field dispersion layer 177a may be located between the source electrode 173 and the drain electrode 175. The gate electrode layer 155 may be covered by a first field dispersion layer 177a. The first field dispersion layer 177a may be electrically connected to the source electrode 173. For example, the first field dispersion layer 177a may be connected to the lower source electrode 173a. The first field dispersion layer 177a may include the same material as the lower source electrode 173a and may be located in the same layer as the lower source electrode 173a. The first field dispersion layer 177a can be formed simultaneously with the lower source electrode 173a in the same process. A boundary between the first field dispersion layer 177a and the lower source electrode 173a is not clear, and the first field dispersion layer 177a may be formed integrally with the lower source electrode 173a. However, it is not limited thereto, and the first field dispersion layer 177a may be a separate component separated from the lower source electrode 173a. Additionally, the first field dispersion layer 177a may be located in a different layer from the lower source electrode 173a and may be formed in a different process. In some cases, the first field dispersion layer 177a may be electrically connected to the gate electrode layer 155. For example, an opening may be formed in the first protective layer 140 that overlaps the gate electrode layer 155, and the first field dispersion layer 177a may be connected to the gate electrode layer 155 through the opening. At this time, the first field dispersion layer 177a may not be connected to the source electrode 173.

The semiconductor device may further include a second field dispersion layer 177b on the second protective layer 150. The second field dispersion layer 177b may form a field dispersion layer together with the first field dispersion layer 177a. The second field dispersion layer 177b may be located between the source electrode 173 and the drain electrode 175. The second field dispersion layer 177b may be overlapped with the gate electrode layer 155 in the third direction D3. The second field dispersion layer 177b may be overlapped with the first field dispersion layer 177a in the third direction D3. The gate electrode layer 155 and the first field dispersion layer 177a may be covered by a second field dispersion layer 177b. The second field dispersion layer 177b may be wider than the width of the first field dispersion layer 177a. The second field dispersion layer 177b may entirely cover the first field dispersion layer 177a. However, it is not limited thereto, and the width, positional relationship, etc. of the first field dispersion layer 177a and the second field dispersion layer 177b may be changed in various ways. The second field dispersion layer 177b may be electrically connected to the source electrode 173. For example, the second field dispersion layer 177b may be connected to the middle source electrode 173b. The second field dispersion layer 177b may include the same material as the middle source electrode 173b and may be located in the same layer as the middle source electrode 173b. The second field dispersion layer 177b may be formed simultaneously with the middle source electrode 173b in the same process. A boundary between the second field dispersion layer 177b and the middle source electrode 173b is not clear, and the second field dispersion layer 177b may be formed integrally with the middle source electrode 173b. However, it is not limited thereto, and the second field dispersion layer 177b may be a separate component separated from the middle source electrode 173b. Additionally, the second field dispersion layer 177b may be located in a different layer from the middle source electrode 173b and may be formed in a different process.

The semiconductor device may further include a third field dispersion layer 177c on the third protective layer 160. The third field dispersion layer 177c may form a field dispersion layer together with the first field dispersion layer 177a and the second field dispersion layer 177b. The third field dispersion layer 177c may be located between the source electrode 173 and the drain electrode 175. The third field dispersion layer 177c may be overlapped with the gate electrode layer 155 in the third direction D3. The third field dispersion layer 177c may be overlapped with the first field dispersion layer 177a and the second field dispersion layer 177b in the third direction D3. The gate electrode layer 155, the first field dispersion layer 177a, and the second field dispersion layer 177b may be covered by a third field dispersion layer 177c. The third field dispersion layer 177c may be wider than a width of the second field dispersion layer 177b. The third field dispersion layer 177c may entirely cover the second field dispersion layer 177b. However, it is not limited thereto, and the width, positional relationship, etc. of the first field dispersion layer 177a, the second field dispersion layer 177b, and the third field dispersion layer 177c may be changed in various ways. The third field dispersion layer 177c may be electrically connected to the source electrode 173. For example, the third field dispersion layer 177c may be connected to the upper source electrode 173c. The third field dispersion layer 177c may include the same material as the upper source electrode 173c and may be located in the same layer as the upper source electrode 173c. The third field dispersion layer 177c may be formed simultaneously with the upper source electrode 173c in the same process. A boundary between the third field dispersion layer 177c and the upper source electrode 173c is not clear, and the third field dispersion layer 177c may be formed integrally with the upper source electrode 173c. However, it is not limited thereto, and the third field dispersion layer 177c may be a separate component separated from the upper source electrode 173c. Additionally, the third field dispersion layer 177c may be located in a different layer from the upper source electrode 173c and may be formed in a different process.

In some embodiments, at least one of the first field dispersion layer 177a, the second field dispersion layer 177b, or the third field dispersion layer 177c may be omitted. For example, the semiconductor device may include the first field dispersion layer 177a and may not include the second field dispersion layer 177b or the third field dispersion layer 177c. Alternatively, the semiconductor device may include the second field dispersion layer 177b and may not include the first field dispersion layer 177a or the third field dispersion layer 177c. Alternatively, the semiconductor device may include the third field dispersion layer 177c and may not include the first field dispersion layer 177a or the second field dispersion layer 177b. Alternatively, the semiconductor device may not include the first field dispersion layer 177a, the second field dispersion layer 177b, and the third field dispersion layer 177c.

FIG. 4 is an enlarged cross-sectional view of portion P of FIG. 2, showing another embodiment.

The embodiment illustrated in FIG. 4 is substantially the same as the embodiment illustrated in FIG. 2, and thus a description thereof will be omitted and the differences will be mainly explained. Additionally, the same reference numerals are used for the same components as in the previous embodiment.

Referring to FIG. 4, the gate semiconductor layer 152 is activated in an oxygen atmosphere, but an oxide layer 152b may not be formed on the surface of the gate semiconductor layer 152.

The gate semiconductor layer 152 may be located on the barrier layer 136. In other words, the gate semiconductor layer 152 may be located between the barrier layer 136 and the gate electrode layer 155. For example, a gate semiconductor layer 152 may be located on a barrier layer 136, and a gate electrode layer 155 may be located on the gate semiconductor layer 152. The upper surface of the gate semiconductor layer 152 may be entirely covered by the gate electrode layer 155. The gate semiconductor layer 152 may be overlapped with the gate electrode layer 155 in the third direction D3.

However, as the gate semiconductor layer 152 is activated in an oxygen atmosphere, the gate semiconductor layer 152 has a low content of impurities such as oxygen, carbon, and hydrogen and its surface roughness does not increase.

For example, the gate semiconductor layer 152 may have an oxygen concentration less than or equal to about 5E17 atom/cm³, for example less than or equal to about 4E17 atom/cm³, less than or equal to about 3E17 atom/cm³, less than or equal to about 2E17 atom/cm³, less than or equal to about 1E17 atom/cm³, less than or equal to about 9E16 atom/cm³, less than or equal to about 8E16 atom/cm³, less than or equal to about 7E16 atom/cm³, or less than or equal to about 6E16 atom/cm³ as measured by secondary ion mass spectrometry. The gate semiconductor layer 152 may have an oxygen concentration greater than or equal to 0 atom/cm³, for example greater than or equal to about 1E 16 atom/cm³, greater than or equal to about 2E16 atom/cm³, greater than or equal to about 3E16 atom/cm³, greater than or equal to about 4E16 atom/cm³, greater than or equal to about 5E16 atom/cm³, greater than or equal to about 6E16 atom/cm³, greater than or equal to about 7E16 atom/cm³, greater than or equal to about 8E16 atom/cm³, or greater than or equal to about 9E16 atom/cm³ as measured by secondary ion mass spectrometry. The gate semiconductor layer 152 may have an oxygen concentration ranging from about 1E16 atom/cm³ to about 5E17 atom/cm³ as measured by secondary ion mass spectrometry.

Additionally, the gate semiconductor layer 152 may have a carbon concentration less than about 1E18 atom/cm³, for example less than or equal to about 9E17 atom/cm³, less than or equal to about 8E17 atom/cm³, less than or equal to about 7E17 atom/cm³, less than or equal to about 6E17 atom/cm³, less than or equal to about 5E17 atom/cm³, less than or equal to about 4E17 atom/cm³, less than or equal to about 3E17 atom/cm³, or less than or equal to about 2E17 atom/cm³ as measured by secondary ion mass spectrometry. The gate semiconductor layer 152 may have a carbon concentration greater than or equal to about 1E17 atom/cm³, for example greater than or equal to about 2E17 atom/cm³, greater than or equal to about 3E17 atom/cm³, greater than or equal to about 4E17 atom/cm³, greater than or equal to about 5E17 atom/cm³, greater than or equal to about 6E17 atom/cm³, greater than or equal to about 7E17 atom/cm³, greater than or equal to about 8E17 atom/cm³, or greater than or equal to about 9E17 atom/cm³ as measured by secondary ion mass spectrometry. The gate semiconductor layer 152 may have a carbon concentration greater than or equal to about 1E17 atom/cm³ and less than about 1E18 atom/cm³ as measured by secondary ion mass spectrometry.

Additionally, the gate semiconductor layer 152 may have a hydrogen concentration less than about 1E18 atom/cm³, for example, for example less than or equal to about 9E17 atom/cm³, less than or equal to about 8E17 atom/cm³, less than or equal to about 7E17 atom/cm³, less than or equal to about 6E17 atom/cm³, less than or equal to about 5E17 atom/cm³, less than or equal to about 4E17 atom/cm³, less than or equal to about 3E17 atom/cm³, or less than or equal to about 2E17 atom/cm³ as measured by secondary ion mass spectrometry. The gate semiconductor layer 152 may have a hydrogen concentration greater than or equal to about 1E17 atom/cm³, for example greater than or equal to about 2E17 atom/cm³, greater than or equal to about 3E17 atom/cm³, greater than or equal to about 4E17 atom/cm³, greater than or equal to about 5E17 atom/cm³, greater than or equal to about 6E17 atom/cm³, greater than or equal to about 7E17 atom/cm³, greater than or equal to about 8E17 atom/cm³, or greater than or equal to about 9E17 atom/cm³ as measured by secondary ion mass spectrometry. The gate semiconductor layer 152 may have a hydrogen concentration of greater than or equal to about 1E17 atom/cm³ and less than about 1E18 atom/cm³ as measured by secondary ion mass spectrometry.

For example, the oxygen concentration, carbon concentration, and hydrogen concentration of the gate semiconductor layer 152 may be measured by secondary ion mass spectrometry (SIMS) using an oxygen ion source (6 kV) at a certain depth in the thickness direction (i.e., the third direction D3) of the gate semiconductor layer 152. The point at which the oxygen concentration, carbon concentration, and hydrogen concentration of the gate semiconductor layer 152 are measured may be a middle point in the width direction of the gate semiconductor layer 152 (i.e., the second direction D2) and a middle point in the thickness direction of the gate semiconductor layer 152 (i.e., the third direction D3). For example, the depth at which the oxygen concentration, carbon concentration, and hydrogen concentration of the gate semiconductor layer 152 are measured may be a point that is about 100 nm deep, about 90 nm deep, about 80 nm deep, about 70 nm deep, about 60 nm deep, about 50 nm deep, about 40 nm deep, about 30 nm deep, about 20 nm deep, about 10 nm deep, about 9 nm deep, about 8 nm deep, about 7 nm deep, about 6 nm deep, about 5 nm deep, about 4 nm deep, about 3 nm deep, about 2 nm deep, or about 1 nm deep from one surface of the gate semiconductor layer 152.

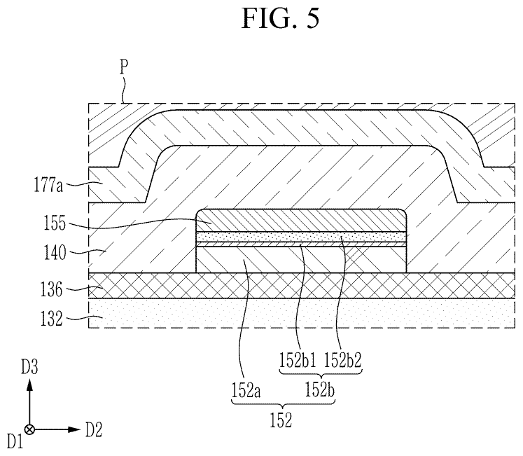

FIG. 5 is an enlarged cross-sectional view of portion P of FIG. 2, showing another embodiment.

The embodiment illustrated in FIG. 5 is substantially the same as the embodiment illustrated in FIG. 2, and thus a description thereof will be omitted and the differences will be mainly explained. Additionally, the same reference numerals are used for the same components as in the previous embodiment.

Referring to FIG. 5, the oxide layer 152b may include a first layer 152b1 on a gate semiconductor material layer 152a, and a second layer 152b2 between the first layer 152b1 and the gate electrode layer 155.

The first layer 152b1 and the second layer 152b2 of the oxide layer 152b may include oxygen and may include the same material as the gate semiconductor material layer 152a with the remaining content excluding oxygen. A boundary between the first layer 152b1 and the second layer 152b2 may not be clearly visible.

For example, the first layer 152b1 may be a native oxide layer, and the second layer 152b2 may be an oxide layer formed by activating the gate semiconductor material layer 152a in an oxygen atmosphere. In other words, the first layer 152b1 may not be formed by activating the gate semiconductor material layer 152a in an oxygen atmosphere like the second layer 152b2, but may be formed as the gate semiconductor material layer 152a is exposed to air.

For example, the thickness of the second layer 152b2 may be greater than the thickness of the first layer 152b1. The first layer 152b1 is a native oxide layer, and since the second layer 152b2 is formed by activating the gate semiconductor material layer 152a in an oxygen atmosphere, the thickness of the second layer 152b2 is relatively thick compared to the thickness of the first layer 152b1, and thus the second layer 152b2 may strengthen the depletion of the gate semiconductor layer 152 and suppress the gate leakage current.

For example, the thickness of the first layer 152b1 may be greater than 0 nm, for example, greater than or equal to about 0.1 nm, greater than or equal to about 0.2 nm, greater than or equal to about 0.3 nm, greater than or equal to about 0.4 nm, greater than or equal to about 0.5 nm, greater than or equal to about 0.6 nm, greater than or equal to about 0.7 nm, greater than or equal to about 0.8 nm, greater than or equal to about 0.9 nm, greater than or equal to about 1.0 nm, greater than or equal to about 1.1 nm, greater than or equal to about 1.2 nm, greater than or equal to about 1.3 nm, greater than or equal to about 1.4 nm, greater than or equal to about 1.5 nm, greater than or equal to about 1.6 nm, greater than or equal to about 1.7 nm, greater than or equal to about 1.8 nm, or greater than or equal to about 1.9 nm. The thickness of the first layer 152b1 may be less than about 2.0 nm, for example, for example, less than or equal to about 1.9 nm, less than or equal to about 1.8 nm, less than or equal to about 1.7 nm, less than or equal to about 1.6 nm, less than or equal to about 1.5 nm, less than or equal to about 1.4 nm, less than or equal to about 1.3 nm, less than or equal to about 1.2 nm, less than or equal to about 1.1 nm, or less than or equal to about 0.9 nm, less than or equal to about 0.8 nm, less than or equal to about 0.7 nm, less than or equal to about 0.6 nm, less than or equal to about 0.5 nm, less than or equal to about 0.4 nm, less than or equal to about 0.3 nm, or less than or equal to about 0.2 nm. The thickness of the first layer 152b1 may be greater than 0 nm and less than about 2 nm.

Additionally, the thickness of the second layer 152b2 may be greater than or equal to about 2 nm, for example, greater than or equal to about 3 nm, greater than or equal to about 4 nm, greater than or equal to about 5 nm, greater than or equal to about 6 nm, greater than or equal to about 7 nm, greater than or equal to about 8 nm, or greater than or equal to about 9 nm. The thickness of the second layer 152b2 may be less than or equal to about 10 nm, for example less than or equal to about 9 nm, less than or equal to about 8 nm, less than or equal to about 7 nm, less than or equal to about 6 nm, less than or equal to about 5 nm, less than or equal to about 4 nm, or less than or equal to about 3 nm. The thickness of the second layer 152b2 may be about 2 nm to about 10 nm.

Here, the thickness of the first layer 152b1 may be the shortest distance in the third direction D3 from the lower surface where the first layer 152b1 contacts the gate semiconductor material layer 152a to the upper surface where the first layer 152b1 contacts the second layer 152b2. Additionally, the thickness of the second layer 152b2 may be the shortest distance in the third direction D3 from the lower surface where the second layer 152b2 contacts the first layer 152b1 to the upper surface where the second layer 152b2 contacts the gate electrode layer 155.

In addition, since the first layer 152b1 is a native oxide layer and the second layer 152b2 is formed by activating the gate semiconductor material layer 152a in an oxygen atmosphere, the oxygen concentration measured by secondary ion mass spectrometry of the second layer 152b2 may be greater than the oxygen concentration measured by secondary ion mass spectrometry of the first layer 152b1.

For example, the first layer 152b1 may have an oxygen concentration less than about 1E18 atom/cm³, for example less than or equal to about 9E17 atom/cm³, less than or equal to about 8E17 atom/cm³, less than or equal to about 7E17 atom/cm³, less than or equal to about 6E17 atom/cm³, less than or equal to about 5E17 atom/cm³, less than or equal to about 4E17 atom/cm³, less than or equal to about 3E17 atom/cm³, or less than or equal to about 2E17 atom/cm³ as measured by secondary ion mass spectrometry. The first layer 152b1 may have an oxygen concentration greater than or equal to about 1E17 atom/cm³, for example greater than or equal to about 2E17 atom/cm³, greater than or equal to about 3E17 atom/cm³, greater than or equal to about 4E17 atom/cm³, greater than or equal to about 5E17 atom/cm³, greater than or equal to about 6E17 atom/cm³, greater than or equal to about 7E17 atom/cm³, greater than or equal to about 8E17 atom/cm³, or greater than or equal to about 9E17 atom/cm³ as measured by secondary ion mass spectrometry. The first layer 152b1 may have an oxygen concentration greater than or equal to about 1E17 atom/cm³ and less than about 1E18 atom/cm³ as measured by secondary ion mass spectrometry.

Additionally, the second layer 152b2 may have an oxygen concentration greater than or equal to about 1E18 atom/cm³, for example greater than or equal to about 2E18 atom/cm³, greater than or equal to about 3E18 atom/cm³, greater than or equal to about 4E18 atom/cm³, greater than or equal to about 5E18 atom/cm³, greater than or equal to about 6E18 atom/cm³, greater than or equal to about 7E18 atom/cm³, greater than or equal to about 8E18 atom/cm³, or greater than or equal to about 9E18 atom/cm³ as measured by secondary ion mass spectrometry. The second layer 152b2 may have an oxygen concentration less than or equal to about 1E19 atom/cm³, for example 9E18 atom/cm³, less than or equal to about 8E18 atom/cm³, less than or equal to about 7E18 atom/cm³, less than or equal to about 6E18 atom/cm³, less than or equal to about 5E18 atom/cm³, less than or equal to about 4E18 atom/cm³, less than or equal to about 3E18 atom/cm³, or less than or equal to about 2E18 atom/cm³ as measured by secondary ion mass spectrometry. The second layer 152b2 may have an oxygen concentration ranging from about 1E18 atom/cm³ to about 1E19 atom/cm³ as measured by secondary ion mass spectrometry.

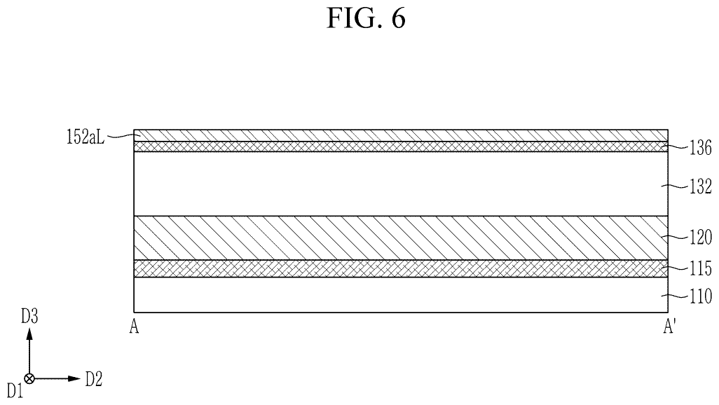

Next, a method for manufacturing a semiconductor device according to an embodiment will be described with reference to FIGS. 6 to 10. In addition, reference may be made to FIGS. 1 to 3 described above.

FIGS. 6 to 10 are cross-sectional views showing a semiconductor device manufacturing method in process order.

Referring to FIG. 6, a seed layer 115, a buffer layer 120, a channel layer 132, and a barrier layer 136 can be sequentially formed on a substrate 110. Additionally, a preliminary gate semiconductor material layer 152aL can be formed on the barrier layer 136.

For example, the seed layer 115, buffer layer 120, channel layer 132, barrier layer 136, and preliminary gate semiconductor material layer 152aL may be formed sequentially using an epitaxial growth method. A seed layer 115 may be first formed on a substrate 110, and a buffer layer 120 may be formed on the seed layer 115. The buffer layer 120 may include a superlattice layer and a high-resistance layer. A channel layer 132 may be formed on the buffer layer 120, a barrier layer 136 may be formed on the channel layer 132, and a preliminary gate semiconductor material layer 152aL may be formed on the barrier layer 136.

For example, equipment for growing the seed layer 115, buffer layer 120, channel layer 132, barrier layer 136, and preliminary gate semiconductor material layer 152aL may use metal organic chemical vapor deposition (MOCVD), hydride vapor phase epitaxy (HVPE), or molecular beam epitaxy (MBE).

The seed layer 115, buffer layer 120, channel layer 132, barrier layer 136, and preliminary gate semiconductor material layer 152aL may be made of the same semiconductor material. However, the material composition ratio of each layer may be different depending on the role of each layer and the performance required for the semiconductor device.

For example, the substrate 110 may include Si, the seed layer 115 may include AlN, and the superlattice layer of the buffer layer 120 may have a structure in which layers made of AlGaN and layers made of GaN are repeatedly stacked. The high-resistance layer of the buffer layer 120 may include GaN, the channel layer 132 may include GaN, and the barrier layer 136 may include AlGaN. The channel layer 132 and the barrier layer 136 may be doped with impurities or may not be doped. The preliminary gate semiconductor material layer 152aL may include GaN and may be doped with impurities. The preliminary gate semiconductor material layer 152aL may be doped with a p-type impurity, for example, magnesium (Mg).

Since the lattice structure of Si and the lattice structure of GaN are different, it may not be easy to grow a channel layer 132 made of GaN directly on a substrate 110 made of Si. Therefore, by first forming a seed layer 115 or a buffer layer 120 on the substrate 110 and then forming the channel layer 132, the lattice structure of the channel layer 132 may be stably formed.

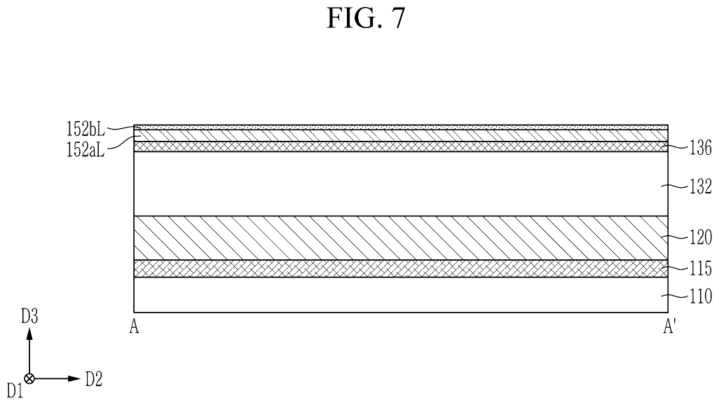

Referring to FIG. 7, the preliminary gate semiconductor material layer 152aL is activated.

For example, in order to manufacture a GaN power semiconductor device having normally off characteristics, an activation process of a preliminary gate semiconductor material layer 152aL is required. For example, a method of activating a preliminary gate semiconductor material layer 152aL including p-type GaN doped with magnesium (Mg) is to apply heat in a nitrogen (N₂) atmosphere. However, during this process, changes such as the mixing of impurities such as oxygen, carbon, and hydrogen and the increase in surface roughness may occur due to the high temperature treatment.

By activating the preliminary gate semiconductor material layer 152aL in an oxygen atmosphere, the activation efficiency of the acceptor can be increased while lowering the temperature of the activation process, and a preliminary oxide layer 152bL can be formed on the surface of the preliminary gate semiconductor material layer 152aL to reduce the content of impurities such as oxygen, carbon, and hydrogen in the preliminary gate semiconductor material layer 152aL, prevent surface roughness from increasing, strengthen the depletion of the preliminary gate semiconductor material layer 152aL, and suppress the gate leakage current.

Since the activation of the preliminary gate semiconductor material layer 152aL is performed in an oxygen atmosphere, the temperature of the activation process can be lowered, and for example, it may be performed at a temperature of less than or equal to about 1000° C., less than or equal to about 900° C., less than or equal to about 800° C., less than about 800° C., less than or equal to about 700° C., less than or equal to about 750° C., less than or equal to about 600° C., less than or equal to about 550° C., less than or equal to about 500°C., less than or equal to about 450° C., or less than or equal to about 400° C., and greater than or equal to about 100° C., greater than or equal to about 150° C., greater than or equal to about 200° C., greater than or equal to about 250° C., greater than or equal to about 300° C., greater than or equal to about 350° C., greater than or equal to about 400° C., greater than or equal to about 450° C., greater than or equal to about 500° C., or greater than or equal to about 550° C., and may be performed at about 350° C. to about 600° C.

The oxygen atmosphere can have an oxygen concentration ranging from about 1 volume % to about 100 volume %, or may be atmospheric (i.e., about 21 volume %) to about 100 volume %. At this time, the oxygen atmosphere may further include an inert gas other than oxygen, and the inert gas may be, for example, nitrogen (N₂) or argon (Ar).

Activation of the preliminary gate semiconductor material layer 152aL may be performed through both in-situ activation, which is performed in the same chamber in which the preliminary gate semiconductor material layer 152aL is grown, and ex-situ activation, which is performed in a different chamber. When the activation of the preliminary gate semiconductor material layer 152aL is performed ex-situ, a native oxide layer may be formed on the surface of the preliminary gate semiconductor material layer 152aL, and as described above in FIG. 5, the oxide layer 152b formed thereafter may include a first layer 152b1 on the gate semiconductor material layer 152a, and a second layer 152b2 between the first layer 152b1 and the gate electrode layer 155.

In some embodiments, activation may additionally proceed in an inert gas atmosphere along with activation in an oxygen atmosphere.

For example, a preliminary gate semiconductor material layer 152aL may be grown, activated in an inert gas atmosphere, and then activated in an oxygen atmosphere. Alternatively, a preliminary gate semiconductor material layer 152aL may be grown, activated in an oxygen atmosphere, and then activated in an inert gas atmosphere. At this time, activation in an oxygen atmosphere and activation in an inert gas atmosphere may each be performed multiple times, and activation in an oxygen atmosphere and activation in an inert gas atmosphere may be performed alternately.

In an inert gas atmosphere, activation may be performed at a temperature of, for example, greater than or equal to about 800° C., for example, greater than or equal to about 850° C., greater than or equal to about 900° C., greater than or equal to about 950° C., or greater than or equal to about 1000° C., and less than or equal to about 1500° C., less than or equal to about 1400° C., less than or equal to about 1300° C., less than or equal to about 1200° C., less than or equal to about 1100° C., less than or equal to about 1000° C., or less than or equal to about 900° C.

The inert gas atmosphere may include an inert gas, such as nitrogen (N₂) or argon (Ar).

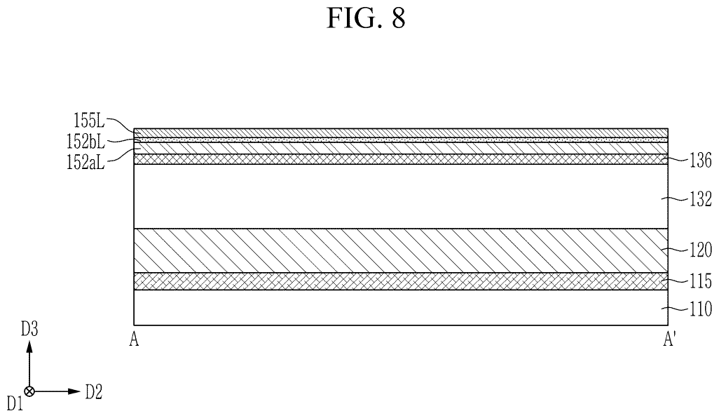

Referring to FIG. 8, a gate electrode material layer 155L may be formed on a preliminary gate semiconductor material layer 152aL on which a preliminary oxide layer 152bL is formed.

For example, the gate electrode material layer 155L may be formed using a deposition process. For example, the gate electrode material layer 155L may be formed using, but is not limited to, electron beam evaporation (E-beam evaporation), sputtering, physical vapor deposition (PVD), thermal chemical vapor deposition (thermal CVD), low pressure chemical vapor deposition (LP-CVD), plasma enhanced chemical vapor deposition (PE-CVD), or atomic layer deposition (ALD).

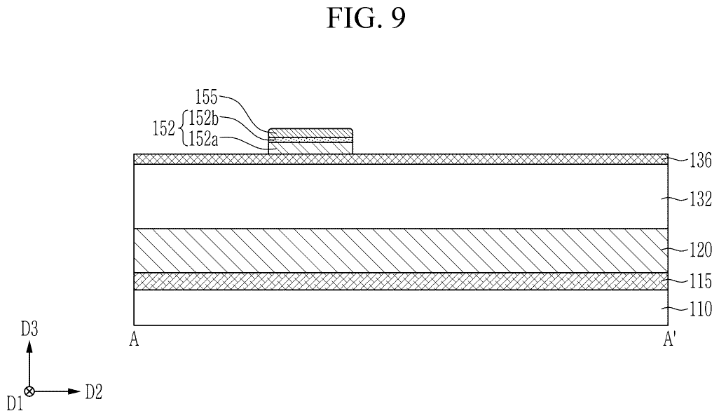

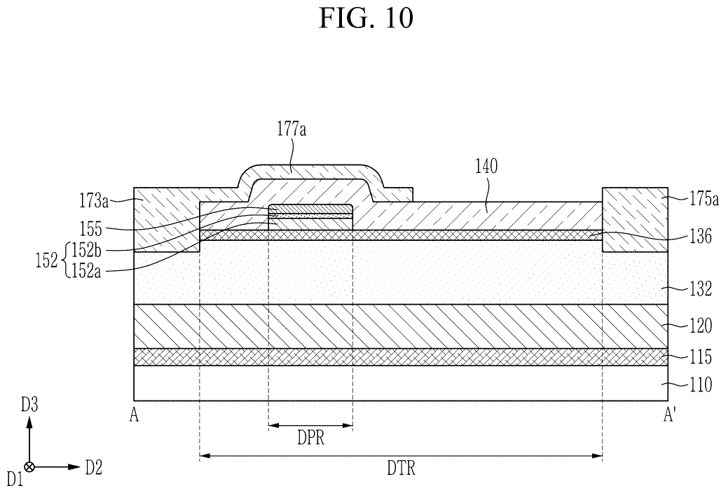

Referring to FIG. 9, the preliminary gate semiconductor material layer 152aL, the preliminary oxide layer 152bL, and the gate electrode material layer 155L are etched to form a gate semiconductor material layer 152a, an oxide layer 152b, and a gate electrode layer 155, respectively.

For example, a hard mask layer (not shown) may be formed on a gate electrode material layer 155L, and a preliminary gate semiconductor material layer 152aL, a preliminary oxide layer 152bL, and a gate electrode material layer 155L may be patterned using the hard mask layer as an etching mask, thereby forming a gate semiconductor material layer 152a, an oxide layer 152b, and a gate electrode layer 155, respectively.

For example, the hard mask layer may be a spin-on hardmask layer (SOH). The spin-on hard mask layer may be formed on the gate electrode material layer 155L through a spin coating process. The hard mask layer may include silicon oxide, silicon nitride, silicon oxynitride, or a combination thereof.

For example, the etching of the preliminary gate semiconductor material layer 152aL, the preliminary oxide layer 152bL, and the gate electrode material layer 155L may be performed by dry etching using an etching gas. The etching gas may contain fluoride gas or chloride gas. For example, the fluoride gas may include, for example, CHF₃, CF₄, or a mixture thereof, and the chloride gas may include, for example, Cl₂, BCl₃, or a mixture thereof.

In some embodiments, after etching the preliminary gate semiconductor material layer 152aL, the preliminary oxide layer 152bL, and the gate electrode material layer 155L, a process of removing byproducts and cleaning the substrate 110 may be performed. For example, byproduct removal may be accomplished through an ashing or stripping process. The ashing process and stripping process may be performed sequentially. For example, an ashing process may be performed first to remove the oxygen (O₂) plasma treatment process or the ozone (O₃) treatment process, and then the stripping process may be performed. Separately from the ashing process or strip process, a process for cleaning the substrate 110 may be performed. For example, the cleaning process may include a dry cleaning process using, for example, NH₃ gas, NF₃ gas, or NF₃ plasma, or a wet cleaning process using HF or BOE. Afterwards, the substrate 110 may be cleaned using a cleaning solution such as ammonia water (NH₄OH).

Referring to FIG. 10, a first protective layer 140 may be formed on the barrier layer 136, the gate semiconductor layer 152, and the gate electrode layer 155. The first protective layer 140 may be formed using a deposition process. The first protective layer 140 may include an insulating material. For example, the first protective layer 140 may include a material such as SiO₂, SiN, SiON, or Al₂O₃. The first protective layer 140 is depicted as a single layer, but may be formed of multiple layers in some cases. At this time, different materials can be sequentially deposited to form a first protective layer 140. Alternatively, by using the same material and varying the deposition conditions, a first protective layer 140 composed of multiple layers with different properties may be formed. In particular, the portion of the first protective layer 140 adjacent to the barrier layer 136 may be made of an insulating material of much better quality than other portions. This is to prevent electrons forming a channel from being trapped within the channel layer 132 under the barrier layer 136. The portion of the first protective layer 140 in contact with the barrier layer 136 may be made of SiO₂.

Next, the first protective layer 140 may be patterned to form a trench, and a lower source electrode 173a and a lower drain electrode 175a may be formed within the trench. At this time, in the process of forming a trench, not only the first protective layer 140 but also a portion of the barrier layer 136 and the channel layer 132 may be patterned together. Additionally, the first field dispersion layer 177a may be formed together in the process of forming the lower source electrode 173a and the lower drain electrode 175a.

The lower source electrode 173a and the lower drain electrode 175a may be in ohmic contact with the channel layer 132. The region in contact with the lower source electrode 173a and the lower drain electrode 175a within the channel layer 132 may be doped at a relatively high concentration compared to other regions. For example, the channel layer 132 may be doped by an ion implant process, an annealing process, etc. However, it is not limited to this, and the doping process of the channel layer 132 may be performed through various other processes. The doping process of the channel layer 132 may be performed before forming the lower source electrode 173a and the lower drain electrode 175a. In some cases, the channel layer 132 may not be doped.

Referring again to FIGS. 1 to 3, a second protective layer 150 may be formed on the first protective layer 140, the lower source electrode 173a, the lower drain electrode 175a, and the first field dispersion layer 177a, the second protective layer 150 may be patterned to form a trench, and a middle source electrode 173b and a middle drain electrode 175b may be formed within the trench, and the second field dispersion layer 177b may be formed together.

In addition, a third protective layer 160 may be formed on the second protective layer 150, the middle source electrode 173b, the middle drain electrode 175b, and the second field dispersion layer 177b, the third protective layer 160 may be patterned to form a trench, and an upper source electrode 173c and an upper drain electrode 175c may be formed within the trench, and the third field dispersion layer 177c may be formed together.

While this disclosure has been described in connection with what is presently considered to be practical embodiments, it is to be understood that the disclosure is not limited to the disclosed embodiments, but, on the contrary, is intended to cover various modifications and equivalent arrangements included within the spirit and scope of the appended claims.

What is claimed is:

1. A semiconductor device, comprising
a channel layer,
a barrier layer located on the channel layer and including a material having an energy bandgap different from that of the channel layer,
a gate electrode layer located on the barrier layer and extending in a first direction,
a gate semiconductor layer disposed between the barrier layer and the gate electrode layer, and
a source electrode and a drain electrode connected to the channel layer and spaced apart from the gate electrode layer in a second direction different from the first direction,
wherein the gate semiconductor layer includes a gate semiconductor material layer disposed on the barrier layer, and an oxide layer disposed between the gate semiconductor material layer and the gate electrode layer.

2. The semiconductor device of claim 1, wherein
the oxide layer has an oxygen concentration greater than or equal to about 1E18 atom/cm³ as measured by secondary ion mass spectrometry (SIMS).

3. The semiconductor device of claim 2, wherein
the oxide layer has an oxygen concentration ranging from about 1E18 atom/cm³ to about 1E19 atom/cm³ as measured by secondary ion mass spectrometry.

4. The semiconductor device of claim 1, wherein
the oxide layer has a thickness ranging from about 1 nm to about 10 nm.

5. The semiconductor device of claim 1, wherein
the oxide layer has a thickness ranging from about 2 nm to about 5 nm.

6. The semiconductor device of claim 1, wherein
the oxide layer comprises:
a first layer disposed on the gate semiconductor material layer; and
a second layer disposed between the first layer and the gate electrode layer.

7. The semiconductor device of claim 6, wherein
a thickness of the second layer of the oxide layer is greater than a thickness of the first layer.

8. The semiconductor device of claim 6, wherein
a thickness of the second layer of the oxide layer ranges from about 2 nm to about 10 nm, and
a thickness of the first layer of the oxide layer is greater than 0 nm and less than about 2 nm.

9. The semiconductor device of claim 6, wherein
an oxygen concentration measured by secondary ion mass spectrometry of the second layer of the oxide layer is greater than an oxygen concentration measured by secondary ion mass spectrometry of the first layer of the oxide layer.

10. The semiconductor device of claim 1, wherein
the gate semiconductor material layer comprises a nitride including Al, Ga, In, B, or a combination thereof.

11. The semiconductor device of claim 1, wherein
an oxygen concentration measured by secondary ion mass spectrometry of the oxide layer is greater than an oxygen concentration measured by secondary ion mass spectrometry of the gate semiconductor material layer.

12. The semiconductor device of claim 1, wherein
the gate semiconductor material layer has an oxygen concentration less than or equal to about 5E17 atom/cm³ as measured by secondary ion mass spectrometry.

13. The semiconductor device of claim 1, wherein
the gate semiconductor material layer has a carbon concentration less than or equal to about 1E18 atom/cm³ as measured by secondary ion mass spectrometry.

14. The semiconductor device of claim 1, wherein
the gate semiconductor material layer has a hydrogen concentration less than or equal to about 1E18 atom/cm³ as measured by secondary ion mass spectrometry.

15. A semiconductor device, comprising
a channel layer,
a barrier layer located on the channel layer and including a material having an energy bandgap different from that of the channel layer,
a gate electrode layer located on the barrier layer and extending in a first direction,
a gate semiconductor layer disposed between the barrier layer and the gate electrode layer, and
a source electrode and a drain electrode connected to the channel layer and spaced apart from the gate electrode layer in a second direction different from the first direction,
wherein the gate semiconductor layer has an oxygen concentration less than or equal to about 5E17 atom/cm³ as measured by secondary ion mass spectrometry (SIMS).

16. The semiconductor device of claim 15, wherein
the gate semiconductor layer has a carbon concentration less than or equal to about 1E18 atom/cm³ as measured by secondary ion mass spectrometry.

17. The semiconductor device of claim 15, wherein
the gate semiconductor layer has a hydrogen concentration less than or equal to about 1E18 atom/cm³ as measured by secondary ion mass spectrometry.

18. A semiconductor device, comprising
a channel layer,
a barrier layer located on the channel layer and including a material having an energy bandgap different from that of the channel layer,
a gate electrode layer located on the barrier layer and extending in a first direction,
a gate semiconductor layer disposed between the barrier layer and the gate electrode layer, and
a source electrode and a drain electrode connected to the channel layer and spaced apart from the gate electrode layer in a second direction different from the first direction,
wherein the gate semiconductor layer includes a gate semiconductor material layer disposed on the barrier layer, and an oxide layer disposed between the gate semiconductor material layer and the gate electrode layer,
the gate semiconductor material layer has an oxygen concentration less than or equal to about 5E17 atom/cm³ as measured by secondary ion mass spectrometry (SIMS), and
the oxide layer has an oxygen concentration ranging from about 1E18 atom/cm³ to about 1E19 atom/cm³ as measured by secondary ion mass spectrometry.

19. The semiconductor device of claim 18, wherein
the gate semiconductor material layer has a carbon concentration less than or equal to about 1E18 atom/cm³ as measured by secondary ion mass spectrometry.

20. The semiconductor device of claim 18, wherein
the gate semiconductor material layer has a hydrogen concentration less than or equal to about 1E18 atom/cm³ as measured by secondary ion mass spectrometry.
